(19) United States
(12) Patent Application Publication
(10) Pub. No.: US 2020/0295111 A1
(43) Pub. Date: Sep. 17, 2020

(54) OLED DISPLAY DEVICE AND MANUFACTURING METHOD FOR THE OLED DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Sihang BAI, Wuhan (CN); Yuan ZHENG, Wuhan (CN)

(21) Appl. No.: 16/492,133

(22) PCT Filed: Apr. 28, 2019
(86) PCT No.: PCT/CN2019/084766

§ 371 Date: Sep. 8, 2019

(30) Foreign Application Priority Data
Mar. 13, 2019 (CN) 201910188094.2

(51) Int. Cl. H01L 27/32

(52) U.S. Cl. CPC H01L 27/3276; H01L 2227/323; H01L 27/3246; H01L 27/3258

(57) ABSTRACT

An OLED display device includes a display area and a non-display area. A plurality of signal wires, a bending area, and a bonding area are disposed in the non-display area. The signal wires located at the bending area at least include a VDD signal wire and a VSS signal wire, and an organic layer insulation layer is disposed in the bending area. An edge length at an end of a part of the organic layer insulation layer between the VDD signal wire and the VSS signal wire is greater than or equal to 3000 micrometers.

### FIELD OF INVENTION

The present application relates to the technical field of display, and especially to an organic light-emitting diode (OLED) display device and a manufacturing method for the OLED display device.

### BACKGROUND OF INVENTION

Currently, active-matrix organic light-emitting diode (AMOLED) displays, having advantages such as being light, thin, bendable, not fragile and wearable, become an outstanding representative in the next generation's display technology. However there are still many technical problems that need to be solved. First, bending performance is the most important measuring standard, and in order to reduce the risk of excessive stress produced when a product is bent, companies are working hard on research in choosing materials and optimizing structures of the bending area of a panel. Mainstream products mainly adopt multistep etching to remove inorganic film layers in the bending area of a panel, and correspondingly use organic film layers with less stress as a substitute to increase bending performance of the products. But during the course of experiments we found the following risk in a manufacturing process: linear residues of a source and drain metal layer occurs at the edge of an organic film layer, and with the distance between a VDD signal wire (constant high voltage level signal wire) and a VSS signal wire (constant low voltage level signal wire) being between about 100 and 200 micrometers, the residual source and drain metal layer between the VDD signal wire and the VSS signal wire will lead to a short of the VDD signal wire and the VSS signal wire, and therefore an abnormal signal occurs.

In short, because the conventional OLED display devices adopt an organic film layer with less stress in the bending area, linear residues of a source and drain metal layer will occur at the edge of the organic film layer, leading to a short of the VDD signal wire and the VSS signal wire due to the undersized distance, and therefore an abnormal signal will occur.

### SUMMARY OF INVENTION

Because the conventional OLED display devices adopt an organic film layer with less stress in a bending area, linear residues of a source and drain metal layer will occur at the edge of the organic film layer, leading to a short of a VDD signal wire and a VSS signal wire due to the undersized distance, and therefore an abnormal signal will occur.

The present application provides an OLED display device and a manufacturing method for the OLED display device that can increase space for residues of a source and drain metal layer at the edge of an organic film layer to overcome the technical problem that because the conventional OLED display devices adopt the organic film layer with less stress in the bending area, linear residues of the source and drain metal layer will occur at the edge of the organic film layer, leading to a short of the VDD signal wire and the VSS signal wire due to the undersized distance, and therefore an abnormal signal will occur.

The present application provides the following technical approach to overcome the above mentioned problem.

The present application provides an OLED display device including a display area, and a non-display area located at one end of the display area. A plurality of signal wires, a bending area, and a bonding area are disposed in the non-display area. One end of each of the signal wires is connected to the display area, and corresponding other end of each of the signal wires extends to the bonding area through the bending area. The signal wires located at the bending area at least include power wires and data signal wires, an organic layer insulation layer is disposed in the bending area, and the power wires are parallel with the signal wires adjacent thereto and respectively pass an edge of the organic layer insulation layer. In the bending area, an edge length of a part of the organic layer insulation layer between the power wires and the signal wires adjacent thereto is greater than or equal to a width of the power wires.

The OLED display device according to an embodiment of the present application, wherein the power wires include a VDD signal wire and a VSS signal wire, and in the bending area, the VDD signal wire and the VSS signal wire or the data signal wires adjacent thereto are parallel with each other, and respectively pass the edge of the organic layer insulation layer.

The OLED display device according to an embodiment of the present application, wherein a range of a distance between the VDD signal wire in the bending area and the VSS signal wire adjacent thereto is between 3000 and 5000 micrometers.

The OLED display device according to an embodiment of the present application, wherein in the bending area, an edge of a part of the organic layer insulation layer between the VDD signal wire and the VSS signal wire adjacent thereto is shaped like a square waveform.

The OLED display device according to an embodiment of the present application, wherein a part of the OLED display device located at the bending area includes a flexible underlying layer, a barrier layer, a buffer layer, a first gate insulation layer, a second gate insulation layer, an inorganic layer insulation layer, the organic layer insulation layer, a source and drain metal layer, a planarization layer, a pixel defining layer and a pixel supporting layer. The organic layer insulation layer is connected to the flexible underlying layer through the inorganic layer insulation layer, the second gate insulation layer, the first gate insulation layer, the buffer layer and the barrier layer.

The OLED display device according to an embodiment of the present application, wherein the flexible underlying layer is made of polyimide, the buffer layer is made of one or two of silicon nitride and silica, the organic layer insulation layer is made of organic photoresist, the first gate buffer layer is made of silicon nitride or silica, the second gate buffer layer is made of what is the same as the first gate buffer layer is made of, and the source and drain metal layer is made of titanium or alloys of titanium and aluminum.

The present application further provides a manufacturing method for an OLED display device including S10, providing a substrate, preparing a flexible underlying layer on a surface of the substrate, preparing a barrier layer and a buffer layer in order on a surface of the flexible underlying layer, preparing an active layer on a surface of the buffer layer, preparing a first gate insulation layer on the surface of the buffer layer, wherein the first gate insulation layer completely covers the active layer, preparing a first gate metal layer on a surface of the first gate insulation layer, forming a second gate insulation layer that completely covers the first gate metal layer on the first gate insulation layer, preparing a second gate metal layer on the second gate insulation layer, and preparing an inorganic layer insulation layer on the second gate metal layer; S20, dry etching the barrier layer, the buffer layer, the first gate insulation layer, the second gate insulation layer and the inorganic layer insulation layer through masks, forming a trench in a non-display area, wherein the trench exposes the flexible underlying layer, and filling in the trench to form an organic layer insulation layer; S30, parallelly disposing power wires with signal wires adjacent thereto in a bending area to make the power wires and the signal wires respectively pass an edge of the organic layer insulation layer such that an edge length at an end of a part of the organic layer insulation layer between the power wires and the signal wires adjacent thereto is greater than or equal to a width of the power wires; S40, preparing a source and drain metal layer and a planarization layer in order on a surface of the inorganic layer insulation layer, wherein the planarization layer completely covers the source and drain metal layer, preparing an anode metal layer, a pixel defining layer and a pixel supporting layer in order on a surface of the planarization layer, wherein a part of the anode metal layer is directly connected to the source and drain metal layer, and removing the substrate.

The manufacturing method for an OLED display device according to an embodiment of the present application, wherein in step S30, the power wires include a VDD signal wire and a VSS signal wire, and in the bending area, the VDD signal wire and the VSS signal wire or data signal wires adjacent thereto are parallel with each other, and respectively pass the edge of the organic layer insulation layer.

The manufacturing method for an OLED display device according to an embodiment of the present application, wherein a range of a distance between the VDD signal wire in the bending area and the VSS signal wire adjacent thereto is between 3000 and 5000 micrometers.

The manufacturing method for an OLED display device according to an embodiment of the present application, wherein in the bending area, an edge of a part of the organic layer insulation layer between the VDD signal wire and the VSS signal wire adjacent thereto is shaped like a square waveform.

The beneficial effect of the present application is that the OLED display device and manufacturing method for the OLED display provided by the present application configure the edge length at an end of a part of the organic layer insulation layer between the power wire in the bending area and the signal wire adjacent thereto to be greater than or equal to the width of the power wire, to increase space for residues of the source and drain metal layer at the edge of the organic film layer, and therefore decrease the risk of a short between adjacent signal wires.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a structure schematic view of the OLED display device according to the present application.

FIG. 2 is a magnified sectional view of the OLED display device at area A of FIG. 1 according to the present application.

FIG. 3A is a magnified top view of the OLED display device at area B of FIG. 2 according to the first embodiment of the present application.

FIG. 3B is a magnified top view of the OLED display device at area B of FIG. 2 according to the second embodiment of the present application.

FIG. 4 is a flowchart of the manufacturing method for an OLED display device according to the present application.

FIG. 5A-FIG. 5D is a schematic view of the manufacturing method for an OLED display device according to the present application.

### DETAILED DESCRIPTION OF PREFERRED EMBODIMENTS

The embodiments of the present disclosure are described in detail hereinafter. Examples of the described embodiments are given in the accompanying drawings. In the description of the present disclosure, it should be understood that terms such as “upper,” “lower,” “front,” “rear,” “left,” “right,” “inside,” “outside,” as well as derivative thereof should be construed to refer to the orientation as shown in the drawings under discussion. These relative terms are for convenience of description and shall not be construed as causing limitations to the present disclosure. The identical reference numerals constantly denote the similar elements.

The present application directs to the technical problem that because the conventional organic light-emitting diode (OLED) display devices adopt an organic film layer with less stress in a bending area, linear residues of a source and drain metal layer will occur at the edge of the organic film layer, leading to a short of a VDD signal wire and a VSS signal wire due to the undersized distance, and therefore an abnormal signal will occur. The present embodiment can overcome this drawback.

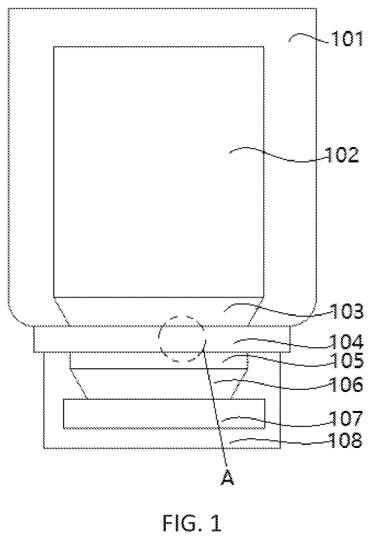

As shown in FIG. 1, the present application provides an OLED display device 101 including a display area 102, and a non-display area 108 located at one end of the display area 102. A plurality of signal wires, a bending area 104, and a bonding area 107 are disposed in the non-display area 108. One end 103 of each of the signal wires is connected to the display area 102, and corresponding other end 106 of each of the signal wires extends to the bonding area 107 through the bending area 104. The lower end of the bending area 104 is connected to a test circuit 105.

In particular, the plurality of signal wires includes array substrate column driving signal wires, power wires and data signal wires connected to the display area 102 from a back board, and the signal wires are made of Ti/Al materials with better ductility.

The power wires include a VDD signal wire and a VSS signal wire, and, in the bending area, the VDD signal wire is parallel with the VSS signal wire or the data signal wire adjacent thereto.

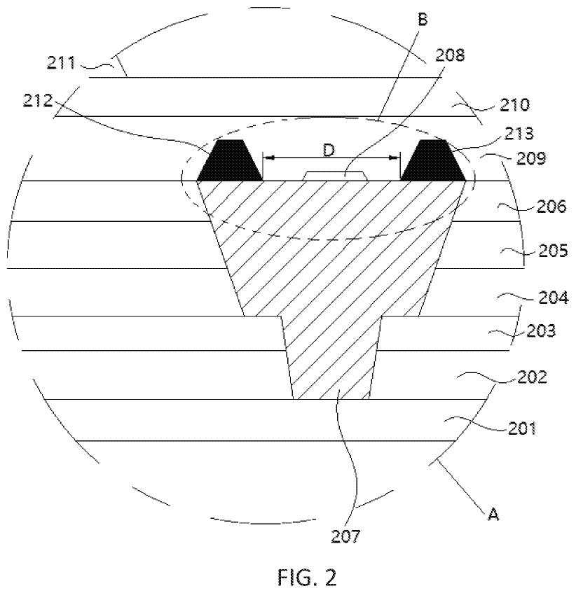

FIG. 2 is a magnified sectional view at area A (bending area 104) of the OLED display device according to the present application. A part of the OLED display device located at the bending area 104 (area A) includes a flexible underlying layer 201, a barrier layer 202, a buffer layer 203, a first gate insulation layer 204, a second gate insulation layer 205, an inorganic layer insulation layer 206, an organic layer insulation layer 207, a source and drain metal layer 208, a planarization layer 209, a pixel defining layer 210 and a pixel supporting layer 211. The organic layer insulation layer 207 is connected to the flexible underlying layer 201 through the inorganic layer insulation layer 206, the second gate insulation layer 205, the first gate insulation layer 204, the buffer layer 203 and the barrier layer 202.

In particular, a plurality of signal wires is disposed on the surface of the organic layer insulation layer 207, including array substrate column driving signal wires, power wires and data signal wires, and the signal wires are made of Ti/Al materials with better ductility. In the bending area 104, the power wires are parallel with the signal wires adjacent thereto and respectively pass an edge of the organic layer insulation layer 207. An edge length of a part of the organic layer insulation layer 207 between the power wires and the signal wires adjacent thereto is greater than or equal to a width of the power wires. The range of the width of the power wires is between 700 and 800 micrometers.

In particular, the power wires include a VDD signal wire 212 and a VSS signal wire 213, and in the bending area 104, the VDD signal wire 212 and the VSS signal wire 213 or the data signal wires adjacent thereto are parallel with each other, and respectively pass the edge of the organic layer insulation layer 207.

In particular, the organic layer insulation layer 207 is made of organic photoresist.

In particular, the flexible underlying layer 201 is made of polyimide, the buffer layer 203 is made of one or two of silicon nitride and silica, the first gate buffer layer 204 is made of silicon nitride or silica, the second gate buffer layer 205 is made of what is the same as the first gate buffer layer 204 is made of, and the source and drain metal layer 208 is made of titanium or alloys of titanium and aluminum.

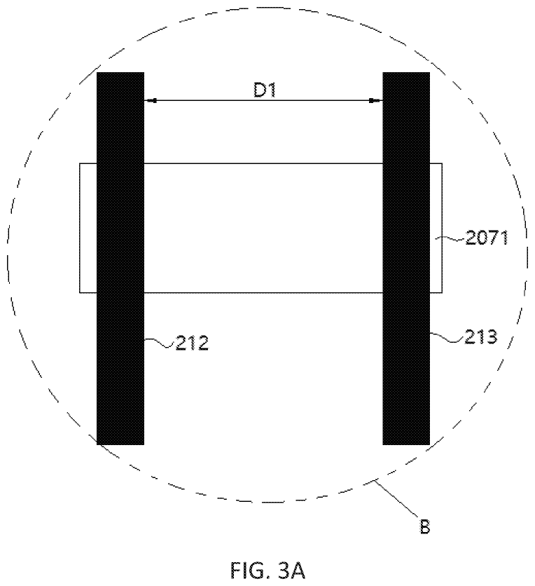

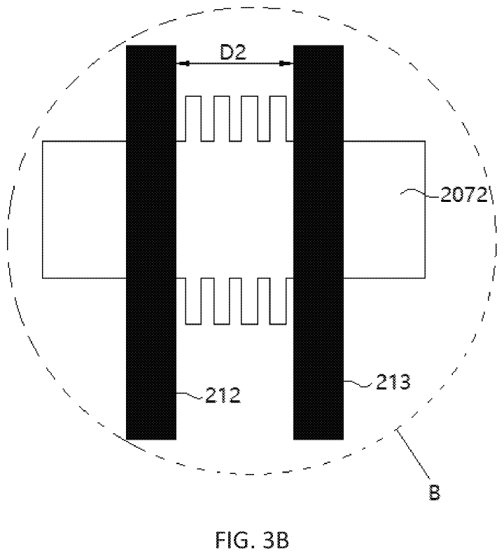

FIG. 3A is a magnified top view of the OLED display device at area B of FIG. 2 according to the first embodiment of the present application. The VDD signal wire 212 and the VSS signal wire 213 are parallel with each other and respectively pass the edge of the organic layer insulation layer 2071. A range of a distance D1 between the VDD signal wire 212 and the VSS signal wire 213 adjacent thereto is between 3000 and 5000 micrometers, that is, an edge length of a part of the organic layer insulation layer 2071 between the VDD signal wire 212 and the VSS signal wire 213 adjacent thereto is greater than or equal to a width of the VDD signal wire 212 or that of the VSS signal wire 213.

The OLED display device according to the first embodiment of the present application increases the distance between the VDD signal wire 212 and the VSS signal wire 213 adjacent thereto to be between 3000 and 5000 micrometers, and in comparison with the conventional technologies having the distance between the VDD signal wire 212 and the VSS signal wire 213 adjacent thereto being between 100 and 200 micrometers, increases the space for residues of the source and drain metal layer 208 at the edge of the organic film layer 2071. With source and drain metal granules at any place in the space for residues break off, the problem of a short circuit of signals will be prevented, and this design can help to decrease the risk of a short of the VDD signal wire 212 and the VSS signal wire 213.

FIG. 3B is a magnified top view of the OLED display device at area B of FIG. 2 according to the second embodiment of the present application. The VDD signal wire 212 and the VSS signal wire 213 are parallel with each other and respectively pass the edge of the organic layer insulation layer 2072. A distance between the VDD signal wire 212 and the VSS signal wire 213 adjacent thereto is D2. An edge of a part of the organic layer insulation layer 2072 between the VDD signal wire and the VSS signal wire is shaped like a square waveform through etching. An edge length of a part of the organic layer insulation layer 2072 between the VDD signal wire 212 and the VSS signal wire 213 adjacent thereto is greater than a width of the VDD signal wire 212 or that of the VSS signal wire 213.

The OLED display device according to the second embodiment of the present application shapes the edge of a part of the organic layer insulation layer 2072 between the VDD signal wire 212 and the VSS signal wire 213 adjacent thereto to be like a square waveform, and increases the space for residues of the source and drain metal layer 208 at the edge of the organic film layer 2072. With metal granules of the source and drain at any place in the space for residues break off, the problem of short circuiting of signals will be prevented, and this design can help to decrease the risk of a short of the VDD signal wire 212 and the VSS signal wire 213.

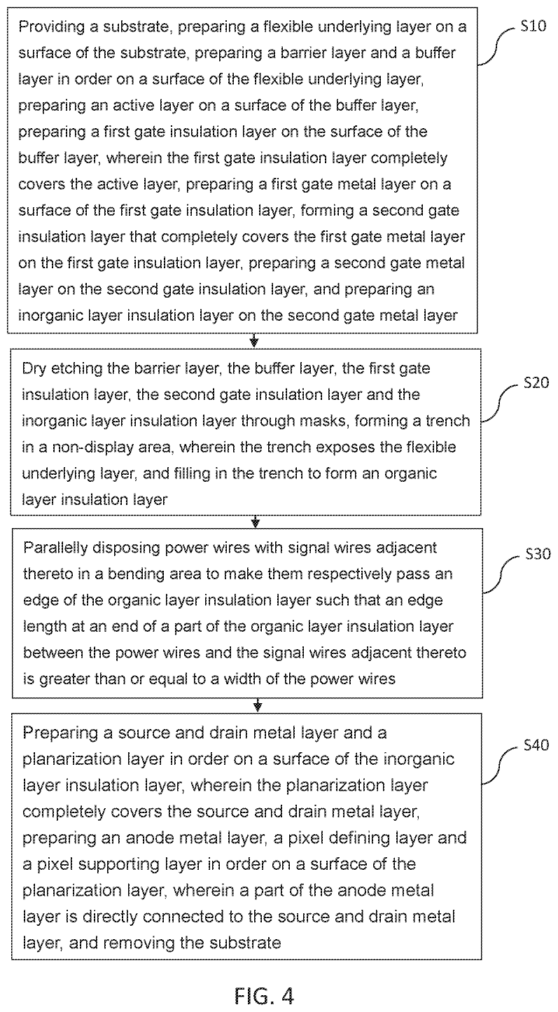

As shown in FIG. 4, the present application further provides a manufacturing method for an OLED display device. The method includes S10, providing a substrate, preparing a flexible underlying layer 501 on a surface of the substrate, preparing a barrier layer 502 and a buffer layer 503 in order on a surface of the flexible underlying layer 501, preparing an active layer 504 on a surface of the buffer layer, preparing a first gate insulation layer 505 on the surface of the buffer layer 503, wherein the first gate insulation layer 505 completely covers the active layer 504, preparing a first gate metal layer 506 on a surface of the first gate insulation layer 505, forming a second gate insulation layer 507 that completely covers the first gate metal layer 506 on the first gate insulation layer 505, preparing a second gate metal layer 508 on the second gate insulation layer 507, and preparing an inorganic layer insulation layer 509 on the second gate metal layer 508.

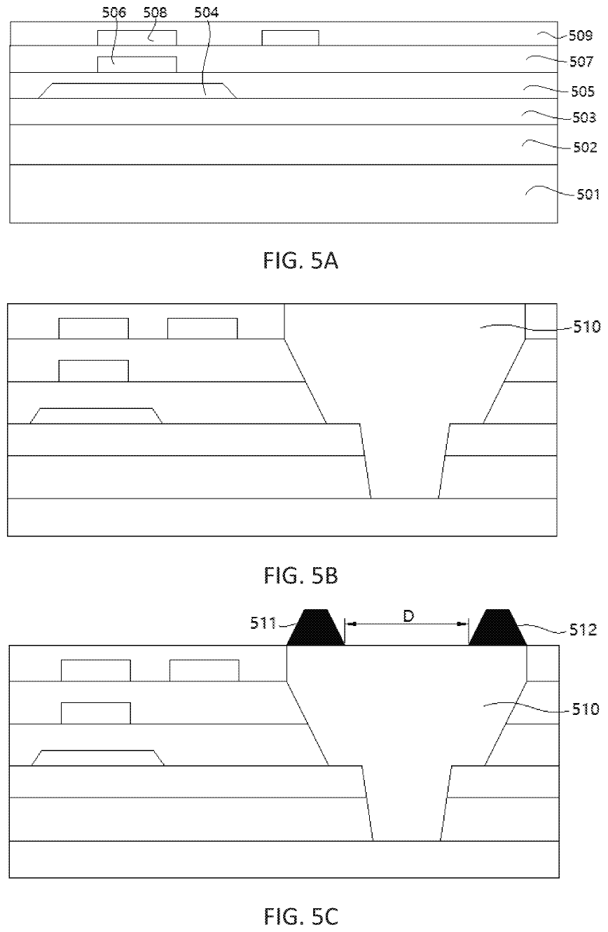

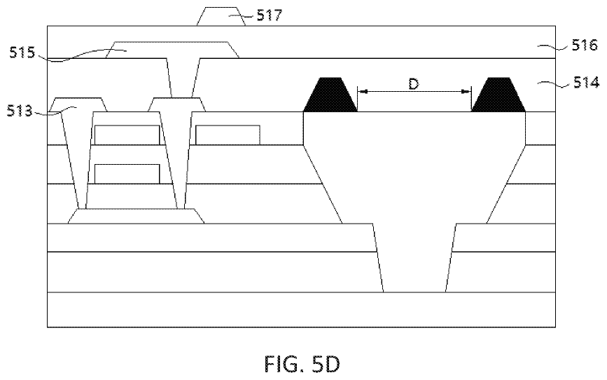

In particular, step S10 further includes, first, providing an insulation substrate, and depositing a layer of flexible underlying layer 501 on the surface of the insulation substrate, wherein the flexible underlying layer 501 is made of polyimide; depositing a barrier layer 502 and a buffer layer 503 in order on the surface of the flexible underlying layer 501 using physical vapor deposition, wherein the barrier layer 502 is made of one or two of silicon nitride and silica, and the buffer layer 503 is made of one or two of silicon nitride and silica; forming a semiconductor layer on the surface of the buffer layer 503, defining the structure of the semiconductor layer by a photolithography process, to form an active layer 504; depositing a first gate insulation layer 505 on the surface of the buffer layer 503, wherein the first gate insulation layer 505 completely covers the active layer 504, and the first gate insulation layer 505 is made of silicon nitride or silica; defining a gate conductor structure on the surface of the first gate buffer layer 505 by a photolithography process to form a first gate metal layer 506, wherein the first gate metal layer 506 is made of molybdenum; depositing a second gate buffer layer 507 on the surface of the first gate buffer layer 505, wherein the second gate buffer layer 507 is made of what is the same as the first gate buffer layer 505 is made of; defining a layer of gate conductor structure on the surface of the second gate buffer layer 507 by a photolithography process to from a second gate metal layer 508, wherein the second gate metal layer 508 is made of molybdenum; and depositing an inorganic layer insulation layer 509 on the second gate metal layer 508, as shown in FIG. 5A.

S20, dry etching the barrier layer 502, the buffer layer 503, the first gate insulation layer 505, the second gate insulation layer 507 and the inorganic layer insulation layer 509 through masks, forming a trench in a non-display area, wherein the trench exposes the flexible underlying layer 501, and filling in the trench to form an organic layer insulation layer 510;

In particular, step S20 further includes, first, dry etching the barrier layer 502, the buffer layer 503, the second gate insulation layer 507, the first gate insulation layer 505 and the inorganic layer insulation layer 509 through masks, and forming a trench in a non-display area, wherein the trench exposes the flexible underlying layer 501, runs through the inorganic layer insulation layer 509, the second gate insulation layer 507, the first gate insulation layer 505, the buffer layer 503 and the barrier layer 502, and terminates in the flexible underlying layer 501; and filling in the trench to form an organic layer insulation layer 510, wherein the organic layer insulation layer 510 is made of organic photoresist, as shown in FIG. 5B.

S30, parallelly disposing power wires with signal wires adjacent thereto in a bending area to make the power wires and the signal wires respectively pass an edge of the organic layer insulation layer 510 such that an edge length at an end of a part of the organic layer insulation layer 510 between the power wires and the signal wires adjacent thereto is greater than or equal to a width of the power wires;

In particular, step S30 further includes, first, disposing a plurality of signal wires on the surface of the organic layer insulation layer 510, including array substrate column driving signal wires, power wires and data signal wires, wherein the signal wires are made of Ti/AI materials with better ductility; and in the bending area, parallelly disposing the power wires with the signal wires adjacent thereto to make the power wires and the signal wires respectively pass the edge of the organic layer insulation layer 510, wherein the edge length of a part of the organic layer insulation layer 510 between the power wires and the signal wires adjacent thereto is greater than or equal to the width of the power wires, and the range of the width of the power wires is between 700 and 800 micrometers.

In particular, the power wires include a VDD signal wire 511 and a VSS signal wire 512, and in the bending area, the VDD signal wire 511 and the VSS signal wire 512 or the data signal wires adjacent thereto are parallel with each other, and respectively pass the edge of the organic layer insulation layer 510.

Advantageously, a range of a distance D between the VDD signal wire 511 and the VSS signal wire 512 adjacent thereto is between 3000 and 5000 micrometers, that is, the edge length of a part of the organic layer insulation layer 510 between the VDD signal wire 511 and the VSS signal wire 512 adjacent thereto is greater than the width of the VDD signal wire 212 or that of the VSS signal wire 213.

Advantageously, an edge of a part of the organic layer insulation layer 510 between the VDD signal wire 511 and the VSS signal wire 512 is shaped like a square waveform through etching. The edge length of a part of the organic layer insulation layer 510 between the VDD signal wire 511 and the VSS signal wire 512 adjacent thereto is greater than the width of the VDD signal wire 511 or that of the VSS signal wire 512, as shown in FIG. 5C.

S40, preparing a source and drain metal layer 513 and a planarization layer 514 in order on a surface of the inorganic layer insulation layer 509, wherein the planarization layer 514 completely covers the source and drain metal layer 513, preparing an anode metal layer 515, a pixel defining layer 516 and a pixel supporting layer 517 in order on a surface of the planarization layer 514, wherein a part of the anode metal layer 515 is directly connected to the source and drain metal layer 513, and removing the substrate.

In particular, step S40 further includes forming a metal layer on the surface of the inorganic layer insulation layer 509, defining the structure of a source and drain conductor layer by a photolithography process, to form a source and drain metal layer 513; depositing a planarization layer 514 on the surface of the inorganic layer insulation layer 509, wherein the planarization layer 514 completely covers the source and drain metal layer 513; depositing an anode metal layer 515, a pixel defining layer 516 and a pixel supporting layer 517 in order on the surface of the planarization layer 514, wherein a part of the anode metal layer 515 is directly connected to the source and drain metal layer 513; and removing the substrate, as shown in FIG. 5D.

The beneficial effect of the present application is that the OLED display device and manufacturing method for the OLED display provided by the present application configure the edge length at an end of a part of the organic layer insulation layer between the power wire in the bending area and the signal wire adjacent thereto to be greater than or equal to the width of the power wire, to increase space for residues of the source and drain metal layer at the edge of the organic film layer, and therefore decrease the risk of a short between adjacent signal wires.

Although the present application has been explained in relation to its preferred embodiment, it does not intend to limit the present application. It will be apparent to those skilled in the art having regard to this present application that other modifications of the exemplary embodiments beyond those embodiments specifically described here may be made without departing from the spirit of the application. Accordingly, such modifications are considered within the scope of the application as limited solely by the appended claims.

What is claimed is:

1. An organic light emitting diode (OLED) display device comprising a display area, and a non-display area located at one end of the display area;
wherein a plurality of signal wires, a bending area, and a bonding area are disposed in the non-display area;
wherein one end of each of the signal wires is connected to the display area, and corresponding other end of each of the signal wires extends to the bonding area through the bending area;
wherein the signal wires located at the bending area at least comprise power wires and data signal wires, an organic layer insulation layer is disposed in the bending area, and the power wires are parallel with the signal wires adjacent thereto and respectively pass an edge of the organic layer insulation layer; and
wherein in the bending area, an edge length of a part of the organic layer insulation layer between the power wires and the signal wires adjacent thereto is greater than or equal to a width of the power wires.

2. The OLED display device as claimed in claim 1, wherein the power wires comprise a VDD signal wire and a VSS signal wire, and in the bending area, the VDD signal wire and the VSS signal wire or the data signal wires adjacent thereto are parallel with each other, and respectively pass the edge of the organic layer insulation layer.

3. The OLED display device as claimed in claim 2, wherein a range of a distance between the VDD signal wire in the bending area and the VSS signal wire adjacent thereto is between 3000 and 5000 micrometers.

4. The OLED display device as claimed in claim 2, wherein in the bending area, an edge of a part of the organic layer insulation layer between the VDD signal wire and the VSS signal wire adjacent thereto is shaped like a square waveform.

5. The OLED display device as claimed in claim 1, wherein a part of the OLED display device located at the bending area comprises a flexible underlying layer, a barrier layer, a buffer layer, a first gate insulation layer, a second gate insulation layer, an inorganic layer insulation layer, the organic layer insulation layer, a source and drain metal layer, a planarization layer, a pixel defining layer and a pixel supporting layer;
wherein the organic layer insulation layer is connected to the flexible underlying layer through the inorganic layer insulation layer, the second gate insulation layer, the first gate insulation layer, the buffer layer and the barrier layer.

6. The OLED display device as claimed in claim 5, wherein the flexible underlying layer is made of polyimide, the buffer layer is made of one or two of silicon nitride and silica, the organic layer insulation layer is made of organic photoresist, the first gate buffer layer is made of silicon nitride or silica, the second gate buffer layer is made of what is the same as the first gate buffer layer is made of, and the source and drain metal layer is made of titanium or alloys of titanium and aluminum.

7. A manufacturing method for an organic light emitting diode (OLED) display device comprising:
S10, providing a substrate, preparing a flexible underlying layer on a surface of the substrate, preparing a barrier layer and a buffer layer in order on a surface of the flexible underlying layer, preparing an active layer on a surface of the buffer layer, preparing a first gate insulation layer on the surface of the buffer layer, wherein the first gate insulation layer completely covers the active layer, preparing a first gate metal layer on a surface of the first gate insulation layer, forming a second gate insulation layer that completely covers the first gate metal layer on the first gate insulation layer, preparing a second gate metal layer on the second gate insulation layer, and preparing an inorganic layer insulation layer on the second gate metal layer;
S20, dry etching the barrier layer, the buffer layer, the first gate insulation layer, the second gate insulation layer and the inorganic layer insulation layer through masks, forming a trench in a non-display area, wherein the trench exposes the flexible underlying layer, and filling in the trench to form an organic layer insulation layer;
S30, parallelly disposing power wires with signal wires adjacent thereto in a bending area to make the power wires and the signal wires respectively pass an edge of the organic layer insulation layer such that an edge length at an end of a part of the organic layer insulation layer between the power wires and the signal wires adjacent thereto is greater than or equal to a width of the power wires;
S40, preparing a source and drain metal layer and a planarization layer in order on a surface of the inorganic layer insulation layer, wherein the planarization layer completely covers the source and drain metal layer, preparing an anode metal layer, a pixel defining layer and a pixel supporting layer in order on a surface of the planarization layer, wherein a part of the anode metal layer is directly connected to the source and drain metal layer, and removing the substrate.

8. A manufacturing method for an OLED display device as claimed in claim 7, wherein in step S30, the power wires comprise a VDD signal wire and a VSS signal wire, and in the bending area, the VDD signal wire and the VSS signal wire or data signal wires adjacent thereto are parallel with each other, and respectively pass the edge of the organic layer insulation layer.

9. The manufacturing method for an OLED display device as claimed in claim 8, wherein a range of a distance between the VDD signal wire in the bending area and the VSS signal wire adjacent thereto is between 3000 and 5000 micrometers.

10. The manufacturing method for an OLED display device as claimed in claim 8, wherein in the bending area, an edge of a part of the organic layer insulation layer between the VDD signal wire and the VSS signal wire adjacent thereto is shaped like a square waveform.
